(19) United States
(12) Patent Application Publication
(10) Pub. No.: US 2008/0017887 A1
(43) Pub. Date: Jan. 24, 2008

(54) THIN FILM TRANSISTOR ARRAY SUBSTRATE, METHOD OF MANUFACTURING THE SAME, AND DISPLAY DEVICE

(75) Inventors: Hitoshi NAGATA, Tokyo (JP); Naoki NAKAGAWA, Tokyo (JP); Takuji IMAMURA, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/778,382

(22) Filed: Jul. 16, 2007

(30) Foreign Application Priority Data
Jul. 18, 2006 (JP) 2006-195670

(51) Int. Cl. H01L 27/10; H01L 21/82

(52) U.S. Cl. 257/204; 438/128; 257/E27.116; 257/E21.535

(57) ABSTRACT

A thin film transistor array substrate according to an embodiment of the present invention includes: a semiconductor layer including a source region having a first conductivity type, a drain region having the first conductivity type, and a channel region between the source region and the drain region, and formed over a substrate; and a gate electrode opposite to the channel region with a gate insulating film interposed therebetween. The channel region contains an impurity of a second conductivity type doped with a predetermined distribution in a film thickness direction, and the impurity of the second conductivity type has a peak concentration point around an interface between the channel region and the insulating substrate or on the insulating substrate side.

### BACKGROUND OF THE INVENTION

1. Field of the Invention

The present invention relates to a thin film transistor array substrate, a method of manufacturing the thin film transistor array substrate, and a display device.

2. Description of Related Art

For an organic EL display device or a liquid crystal display device formed on an insulating substrate such as a glass, a low-temperature polysilicon thin film transistor has come to be used. A performance of the display device has been dramatically improved by utilizing the low-temperature polysilicon thin film transistor (hereinafter referred to as “TFT”). Further, along with development to increase an image quality of the display device, higher performance has been demanded. In particular, in the organic EL display device, an output level of an analog signal varies due to fluctuations of a TFT threshold voltage (Vth) or change in drain current (Id)-drain voltage (Vds) characteristics in a saturation region of the TFT, leading to an uneven image.

FIGS. 12A and 12B are sectional views of a structure of a low-temperature polysilicon TFT of the related art. FIG. 12A is a sectional view taken along the direction in which source/drain regions are formed, and FIG. 12B is a sectional view taken along the direction vertical to the direction of FIG. 12A. As shown in FIG. 12A, a TFT 30 of the related art includes a semiconductor layer 32 including a source region 321, a drain region 322, and a channel region 323 and formed over an insulating substrate 31. Further, a gate insulating film 33 is formed on the semiconductor layer 32, and a gate electrode 34 is formed to cover the channel region 323 on the gate insulating film 33.

In FIG. 12B, the semiconductor layer 32 has a trapezoidal shape in section; its width is reduced from a lower portion to an upper portion, and the layer is tapered at side portions (tapered portions 325). This shape is employed to overcome a problem concerning etching residue and disconnection of the gate electrode 34. However, the tapered portions 325 cause another problem. That is, the tapered portions 325 with a smaller film thickness are formed at both ends of the channel region 323, with the result that TFT characteristics of a usual-thickness portion 326 are mixed with TFT characteristics of the tapered portions 325 with a smaller film thickness.

“Effects of Semiconductor Thickness on Poly-Crystalline Silicon Thin Film Transistors”, Jpn. J. Appl. Phys. Vol. 35 (1996) pp. 923-929, M. Miyasaka, T. Komatsu, W. Itoh, A. Yamaguchi and H. Ohshima (hereinafter referred to as “M. Miyasaka et al.”) describes a relationship between the polysilicon film thickness and TFT characteristics. Here, a threshold voltage Vth of the TFT is derived from Expression 1.

Vth=V_{FB}+2φ_{B}+qN_{A}t_{Si}/Cₒₓ=V₀+qN_{A}t_{Si}/Cₒₓ (1)
V_{FB}: flat band voltage
φ_{B}: Fermi potential based on intrinsic Fermi level
q: charge
N_{A}: acceptor-like trap density
t_{Si}: polysilicon film thickness
Cₒₓ: gate insulating film capacitance

### As is understood from Expression 1, the threshold voltage Vth of the TFT varies depending on a polysilicon film thickness t_{Si}.

In the channel region 323 made of polysilicon, the voltage Vth of the TFT is lower at the tapered portions 325 as apparent from Expression 1. Thus, the tapered portions 325 are shifted to an on state earlier than the main usual-thickness portion 326, at a lower gate voltage. Thus, as understood from drain current (logarithm)-gate voltage characteristics (Id (log)-Vg characteristics: hereinafter referred to as “subthreshold characteristics”) shown in FIG. 13, Id rises even in a lower range of Vg due to the tapered portions 325. However, the channel width of the tapered portion 325 is narrow, so the current Id flowing through the tapered portions 325 is smaller than the usual-thickness portion 326 in a saturation region. As a result, in the saturation region, the TFT characteristics of the usual-thickness portion 326 are dominant. As described above, a hump appears at the point where the drain current (logarithm) increases in the subthreshold characteristic. Here, the degree to which the voltage Vth is changed in accordance with the polysilicon film thickness varies depending on a difference in polysilicon crystallinity (M. Miyasaka et al.). Accordingly, the voltage Vth of the polysilicon TFT is varied in accordance with a shape of the tapered portions 325 in the semiconductor layer 32, and instability of crystallinity at the interface between the semiconductor layer 32 and the insulating substrate 31. That is, the hump of the subthreshold characteristic is changed, and the threshold voltage Vth of the TFT varies.

Next, a relationship between a drain current (Id) and a drain voltage (source-drain voltage: Vds) in a saturation region is described with reference to a graph of FIG. 14. This graph shows an amount of current Id relative to a voltage Vds applied between the source region 321 and the drain region 322. In FIG. 14, plural line graphs are illustrated at varying levels of voltage Vgs applied between the source region 321 and the gate electrode 34 of the TFT. Here, a relationship between Id and Vds in the saturation region is expressed by Expression 2.

Id=β/2(Vgs−Vth)²(1+λVds) (2)

Vgs: source-gate voltage

Vth: threshold voltage

β: constant

Under an ideal state of the TFT, λ=0 in Expression 2. Thus, as indicated by the dotted lines of FIG. 14, Id is uniquely determined based on Vgs irrespective of variations in Vds. The amount of output current Id can be stabilized by controlling the voltage Vgs. However, in the actual TFT, the amount of output current Id is unstable not only at λ=0 but also in the saturation region as indicated by the thick solid lines of FIG. 14. That is, Id varies along with change in Vds even in the saturation region. Thus, the Id-Vds characteristic graph slopes even in the saturation region. The absolute value of the voltage Vds from an intersection between the extensions of the slopes according to gradients derived from Expression 2 as indicated by the solid lines and the axis of Vds (Id=0) to the origin is 1/λ. The value of 1/λ corresponds to an early voltage in a bipolar transistor.

In the bipolar transistor, if a collector-emitter voltage (Vce: Vds in the TFT) increases, a depletion layer at a collector junction (surrounding area of a drain in the TFT) expands. As a result, an effective base width (an effective channel length in the TFT) is reduced, and in addition, a collector current (Ic: Id in the TFT) is increased. This phenomenon is called “Early effect”, and the voltage Vce at the point where the Ic-Vce line is extrapolated to Ic=0 is the early voltage. As current-voltage characteristics of a TFT used in an analog circuit, it is necessary to increase the apparent early voltage (1/λ). That is, it is necessary to approximate λ to 0 to stabilize the saturation region.

Referring to FIG. 12A, a mechanism of how the saturation region fluctuates along with an increase in λ is described in detail next. Here, the TFT is, for example, an n-channel TFT. First, a voltage Vgs higher than the threshold voltage Vth is applied to the gate electrode 34. As a result, carriers are generated in an inversion layer of the channel region 323 near the gate electrode 34. In the n-channel TFT, the carriers are electrons. The electrons move while being accelerated by an electric field generated between the source region 321 and the drain region 322. The accelerated electrons collide against atoms in the channel region 323, with the result that hole-electron pairs are generated. Electrons of the generated hole-electron pairs are absorbed to the drain region 322 along the electric field. Some holes blocked by an energy barrier of the source region 321 are accumulated in the channel region 323 far from the gate electrode 34, that is, on the insulating substrate 31 side. A backgate potential is generated due to the accumulated holes, and the voltage Vth drops. This leads to a phenomenon that the current Id further increases and λ also increases.

As described above, in the TFT 30 of the related art, a hump appears in the subthreshold characteristic because of variations in shape of the tapered portions 325 and crystallinity, and the threshold voltage Vth of the TFT varies. This makes it difficult to control the voltage Vth, and makes the TFT device characteristics unstable. Further, λ increases in the Id-Vds characteristics, and the TFT becomes unstable in the saturation region. In the analog driving circuit, each TFT becomes unstable, resulting in an uneven image of the display device.

Japanese Unexamined Patent Application Publication No. 2005-51172 discloses a technique aimed at solving the above problems. According to this technique, a semiconductor layer is constituted of two independent layers: a lower layer and an upper layer formed between the lower layer and a gate insulating film. The lower layer is a conductivity type opposite to that of a source/drain region, and the upper layer has an impurity concentration enough to drive a channel. These layers are formed by depositing two amorphous silicon layers with CVD (Chemical Vapor Deposition) and then turning the layers into polysilicon layers through laser annealing. However, a crystalline silicon layer generally has a film thickness of about 50 nm or less. Thus, it is difficult to form two crystalline silicon layers independent of each other. In the case of crystallizing the two layers of silicon thin film formed by the CVD through laser annealing, silicon is melted during laser annealing, and conductive impurities greatly diffuses in the melted silicon. This leads to a problem that impurities having an opposite conductivity type reach up to the crystalline silicon layer surface, and the TFT characteristics vary.

### SUMMARY OF THE INVENTION

The present invention has been accomplished with a view to solving the above problems, and it is accordingly an object of the present invention to provide a thin film transistor array substrate with stable performance, a method of manufacturing the thin film transistor array substrate, and a display device.

A thin film transistor array substrate according to an aspect of the present invention includes: a crystalline silicon layer including a source region having a first conductivity type, a drain region having the first conductivity type, and a channel region between the source region and the drain region, and formed over a substrate; and a gate electrode opposite to the channel region with a gate insulating film interposed therebetween, wherein the channel region contains an impurity of a second conductivity type doped with a predetermined distribution in a film thickness direction, and the impurity of the second conductivity type has a peak concentration point around a interface between the channel region and the substrate or on the substrate side.

According to the present invention, it is possible to provide a thin film transistor array substrate with stable performance, a method of manufacturing the thin film transistor array substrate, and a display device.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 shows the structure of a TFT substrate of an liquid crystal display device according to the present invention;

FIGS. 2A to 2C are a plan view and sectional views of a TFT according to a first embodiment of the present invention;

FIGS. 3A to 3F are sectional views of a manufacturing process of the TFT according to the first embodiment;

FIG. 4 is a graph showing a relationship between an ion implantation depth and an impurity concentration.

FIG. 5 is a sectional view of a TFT having an LDD structure according to a second embodiment of the present invention;

FIG. 6 is a sectional view of another example of the TFT having the LDD structure according to the second embodiment;

FIG. 7 is a sectional view of a TFT having a GOLD structure according to the second embodiment;

FIG. 8 is a sectional view of another example of the TFT having the GOLD structure according to the second embodiment;

FIGS. 9A to 9D are a plan view and sectional views of a TFT according to a third embodiment of the present invention;

FIGS. 10A to 10C are a plan view and sectional views of another structure of the TFT according to the third embodiment;

FIGS. 11A to 11G are sectional views of a manufacturing process of the TFT according to the third embodiment;

FIGS. 12A and 12B are sectional views of a TFT of the related art;

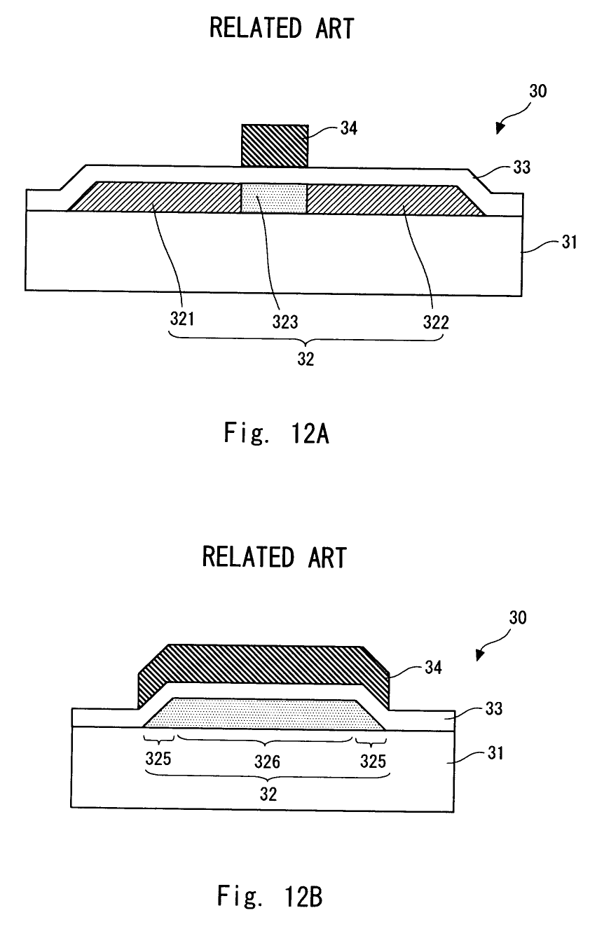

FIG. 13 is a graph of subthreshold characteristics of a TFT; and

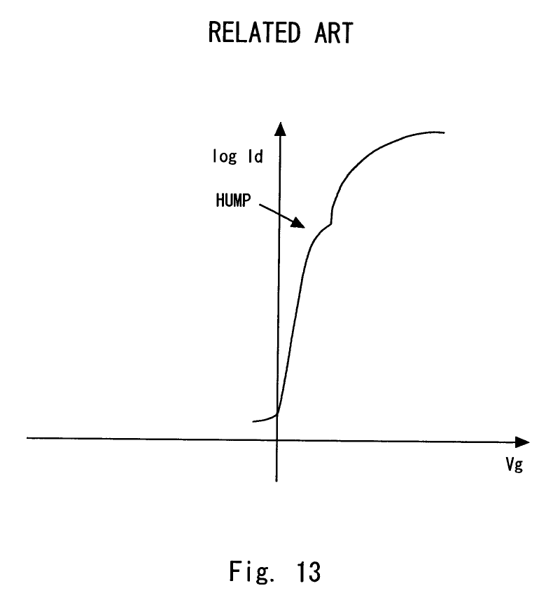

FIG. 14 is a graph of Id-Vds characteristics of a TFT.

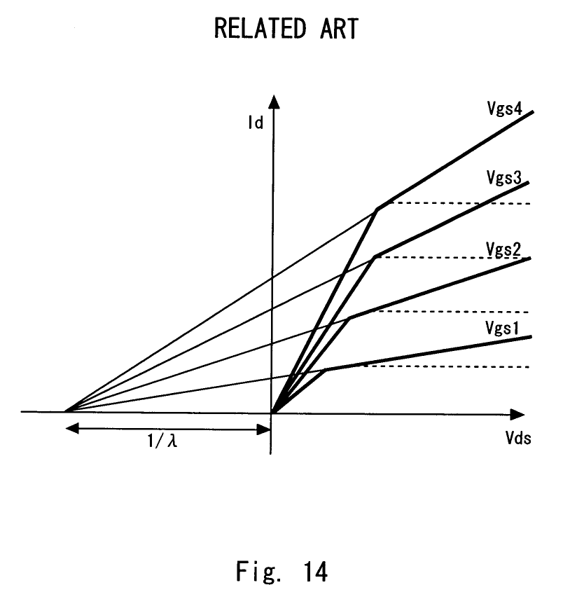

### DESCRIPTION OF THE PREFERRED EMBODIMENTS

Hereinafter, embodiments of the present invention will be described. Some components etc. are omitted or simplified in the following description and the accompanying drawings as appropriate, and repetitive description is omitted if not necessary for ease of illustration.

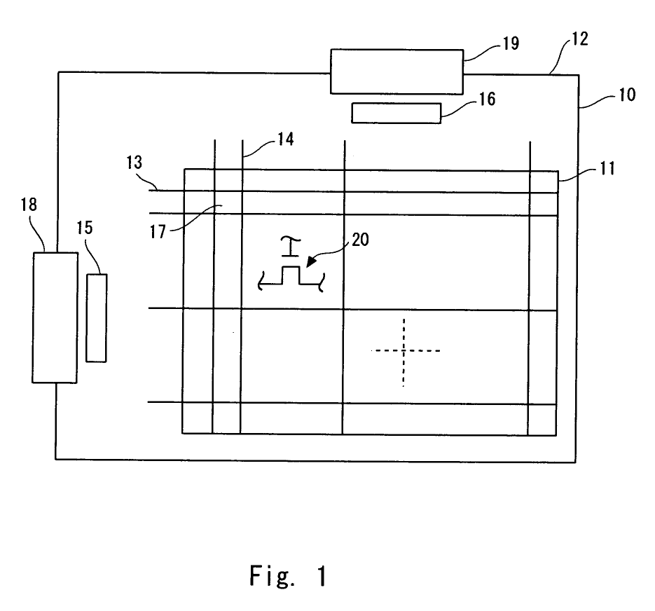

Referring first to FIG. 1, a liquid crystal display device using a TFT array substrate according to the present invention is described. FIG. 1 is a front view showing the structure of the TFT array substrate used in the liquid crystal display device. As a display device according to the present invention, a liquid crystal display device is employed by way of example, and needless to say, a flat display device (flat panel display) such as an organic EL display device can be used. The overall structure of the TFT array substrate is common in the following first to third embodiments.

The display device of the present invention includes a TFT array substrate 10. Within the TFT array substrate 10, a display region 11 and a frame region 12 surrounding the display region are formed. In the display region 11, plural scanning signal lines 13 and plural display signal lines 14 are formed. The plural scanning signal lines 13 are arranged in parallel. Likewise, the plural display signal lines 14 extend in parallel. The scanning signal lines 13 and the display signal lines 14 cross each other. The scanning signal lines 13 and the display signal lines 14 are orthogonal. A region surrounded by adjacent scanning signal lines 13 and display signal lines 14 is a pixel 17. Thus, the pixels 17 are arranged in matrix in the TFT array substrate 10.

Further, in the frame region 12 of the TFT array substrate 10, a scanning signal driving circuit 15 and a display signal driving circuit 16 are formed. The scanning signal lines 13 extend from the display region 11 up to the frame region 12. The scanning signal lines 13 are connected to the scanning signal driving circuit 15 at the end of the TFT array substrate 10. Likewise, the display signal lines 14 extend from the display region 11 to the frame region 12. Further, the display signal lines 14 are connected to the display signal driving circuit 16 at the end of the TFT array substrate 10. An external line 18 is connected near the scanning signal driving circuit 15. Further, an external line 19 is connected near the display signal driving circuit 16. The external lines 18 and 19 constitute, for example, a wiring board such as an FPC (Flexible Printed Circuit).

Various signals are externally supplied through the external lines 18 and 19 to the scanning signal driving circuit 15 and the display signal driving circuit 16. The scanning signal driving circuit 15 supplies a scanning signal to the scanning signal lines 13 based on an external control signal. Based on the scanning signal, the scanning signal lines 13 are selected one by one. The display signal driving circuit 16 supplies display signals to display signal lines 14 based on an external control signals or display data. Thus, a display voltage corresponding to the display data can be applied to each pixel 17. Incidentally, the scanning signal driving circuit 15 and the display signal driving circuit 16 are not necessarily formed on the TFT array substrate 10. For example, a driving circuit may be connected by means of TCP (Tape Carrier Package).

In each pixel 17, at least one TFT 20 is formed. The TFT 20 is positioned around an intersection between the display signal line 14 and the scanning signal line 13. For example, the TFT 20 applies a display voltage to a pixel electrode. That is, The TFT 20 as a switching element is turned on in response to a scanning signal from the scanning signal line 13. As a result, the display signal line 14 applies a display voltage to the pixel electrode connected to a drain electrode of the TFT 20. Then, an electric field corresponding to the display voltage is generated between the pixel electrode and an opposing electrode. Incidentally, an alignment layer (not shown) is formed on the surface of the TFT array substrate 10.

Further, an opposing substrate is placed opposite to the TFT array substrate 10. The opposing substrate is, for example, a color filter substrate and is positioned on a display screen side. Over the opposing substrate, a color filter, black matrix (BM), an opposing electrode, an alignment layer, and the like are formed. Incidentally, the opposing electrode may be placed on the TFT array substrate 10 side. The TFT array substrate 10 and the opposing substrate sandwich a liquid crystal layer. That is, a liquid crystal is filled between the TFT array substrate 10 and the opposing substrate. Further, a polarizing plate, a retardation film, and the like are provided on the outer surfaces of the TFT array substrate 10 and the opposing substrate. In addition, a backlight unit or the like is provided on the opposite side to the display screen side of the liquid crystal display panel.

The liquid crystal is driven by an electric field generated between the pixel electrode and the opposing electrode. That is, an alignment direction of the liquid crystal between the substrates is changed. As a result, a polarization state of light transmitted through the liquid crystal layer is changed. That is, a polarization state of the light linearly polarized through the polarizing plate is changed by the liquid crystal layer. To be specific, light from the backlight unit is linearly polarized through a polarizing plate on the array substrate side. Then, the linearly polarized light changes its polarization state after transmitted through the liquid crystal layer.

Thus, an amount of light transmitted through the polarizing plate on the opposing substrate side is varied in accordance with a polarization state. That is, among transmitted light transmitted from the backlight unit through the liquid crystal display panel, an amount of light further transmitted through the polarizing plate on the display screen side is varied. The alignment direction of the liquid crystal is varied in accordance with an applied display voltage. Therefore, the display voltage is controlled to change an amount of light transmitted through the polarizing plate on the display screen side. That is, by applying a display voltage to pixels at different voltage levels, a desired image can be displayed.

Next, the structure of the TFT 20 is described. In the display device of the present invention, the TFT 20 is formed in the pixel 17 in the display region 11.

### First Embodiment

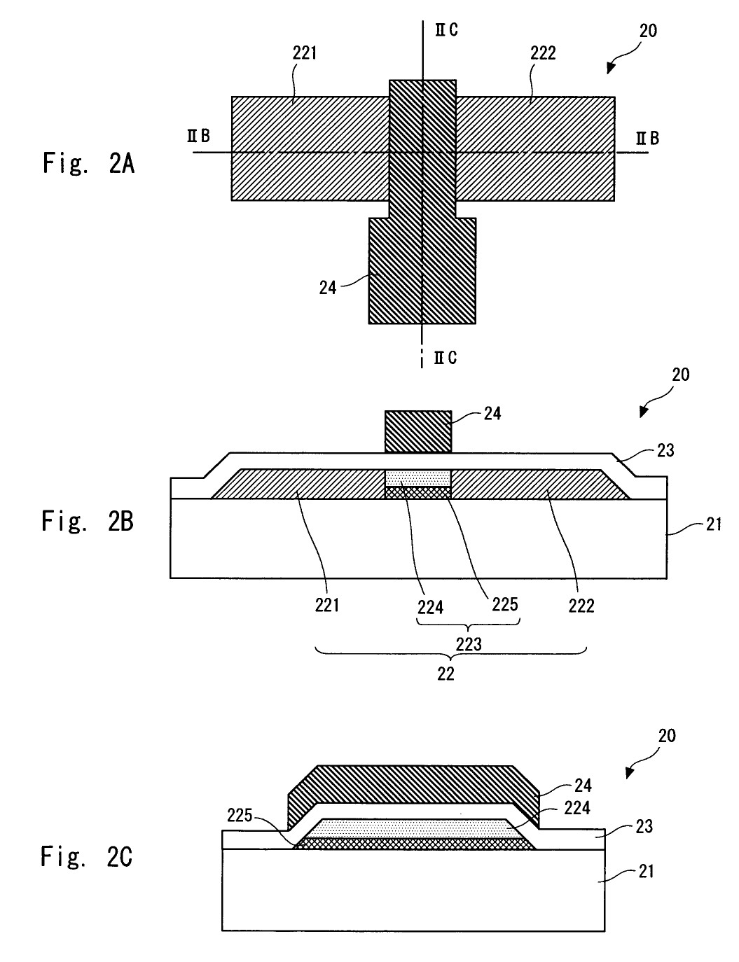

Referring to FIGS. 2A to 2C, a TFT according to a first embodiment of the present invention is described. FIG. 2A is a plan view showing the structure of the TFT 20 according to the first embodiment. FIG. 2B is a sectional view taken along the line IIB-IIB of FIG. 2A. FIG. 2C is a sectional view taken along the line IIC-IIC of FIG. 2A.

In FIGS. 2A to 2C, a semiconductor layer 22 is formed on an insulating substrate 21. The semiconductor layer 22 includes a source region 221 having a first conductivity type, a drain region 222 having the first conductivity type, and a channel region 223. The channel region 223 is positioned between the source region 221 and the drain region 222. Further, a gate insulating film 23 is formed to cover the semiconductor layer 22. A gate electrode 24 is formed opposite to the channel region 223 across the gate insulating film 23. From the viewpoint of increasing a breakdown voltage (preventing short-circuiting) between the gate electrode 24 and the semiconductor layer 22 and preventing disconnection of the gate electrode 24, the semiconductor layer 22 is tapered at end portions. The gate electrode 24 is formed on the gate insulating film 23 while protruding from the semiconductor layer 22.

In this embodiment, the channel region 223 is doped with second conductivity type impurities with a predetermined distribution in the film thickness direction. That is, the second conductivity type impurities are doped to show continuous distribution throughout the channel region 223 in the film thickness direction. In this example, the distribution of the second conductivity type impurities is, for example, Gaussian distribution. The channel region 223 includes two layers: a channel formation layer 224, and a buried impurity layer 225. The channel formation layer 224 is formed on the gate insulating film 23 side. The buried impurity layer 225 is formed on the insulating substrate 21 side. Incidentally, the buried impurity layer 225 is a layer having a peak concentration on the insulating substrate 21 side. Thus, in practice, there is no clear division as illustrated in FIGS. 2A to 2C. Depending on what TFT characteristics are required, the channel region 223 may contain a small amount of second-conductivity-type impurities at the interface with the gate insulating film 23. If a voltage is applied to the gate electrode 24, a channel is formed in the channel formation layer 224. The buried impurity layer 225 has a higher second-conductivity-type impurity concentration than the channel formation layer 224, and has a peak point of the second-conductivity-type impurity concentration around the interface with the insulating substrate 21 or on the insulating substrate 21 side. For example, in an n-channel type TFT, the source region 221 and the drain region 222 of the first conductivity type are n-type regions, and the buried impurity layer 225 of the second conductivity type is a p-type region. The following description is given of an n-channel type TFT for illustrative purposes, but the present invention is not limited thereto, and a p-channel type TFT can be, of course, used.

In Expression 1, a concentration of the buried impurity layer 225 should be increased to an N_{A} level to compensate of the acceptor-like trap state density N_{A}. The value of N_{A} is about 1×10¹⁷/cm³ (M. Miyasaka et al.). Hence, it is desirable to set the concentration of the buried impurity layer 225 to 1×10¹⁶/cm³ or more at the interface with the insulating substrate 21.

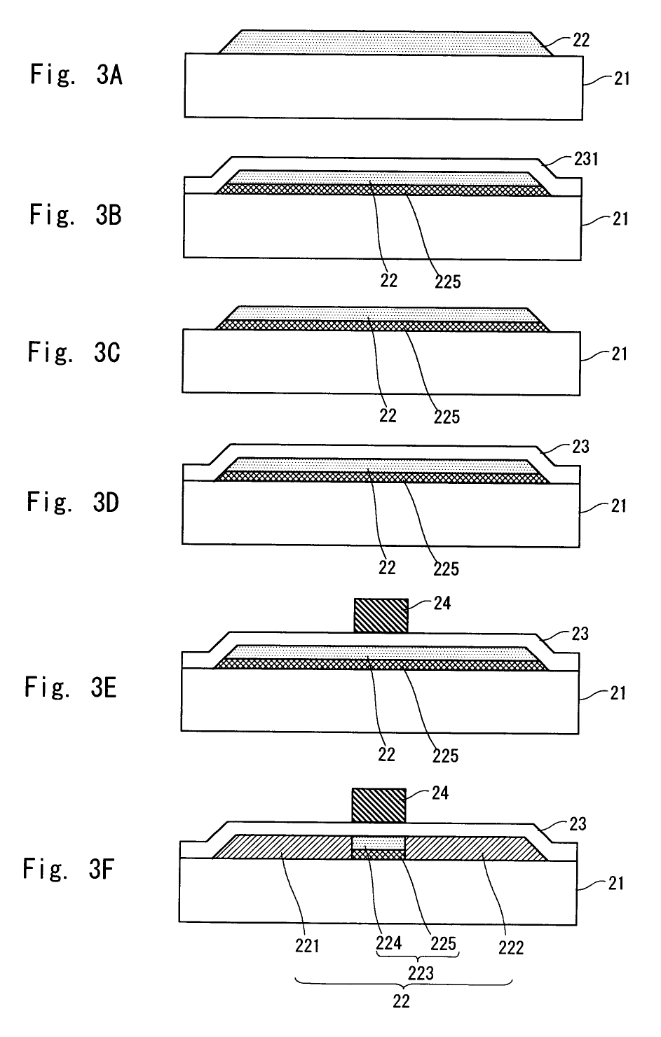

Referring next to FIGS. 3A to 3F, a manufacturing process of the TFT 20 of the first embodiment is described in detail. FIGS. 3A to 3F are sectional views of the TFT taken along the line IIB-IIB of FIG. 2A in a manufacturing process.

First, amorphous silicon is formed on the insulating substrate 21 by plasma CVD (PECVD) or the like. The insulating substrate 21 is formed of, for example, glass. The insulating substrate 21 may be made of quartz, polycarbonate, acrylic, or other such plastics as well as glass. In addition, the substrate 21 may be metal substrate made of SUS or the like with an insulating protective layer formed on the surface. After that, the amorphous silicon is subjected to crystallization with laser annealing or the like and turned into polysilicon. Then, the polysilicon is processed into a desired shape by photolithography including plasma etching or the like. In this way, the semiconductor layer 22 is formed. The semiconductor layer 22 is not limited to the polysilicon layer but may be a crystalline silicon layer such as a microcrystal silicon layer. Through the above processing, the structure of FIG. 3A is completed.

In this embodiment, the buried impurity layer 225 is formed by implanting target ions to the semiconductor layer 22. If the ions are implanted to the semiconductor layer 22 without forming the protective film on its surface, the semiconductor layer 22 is contaminated with substances of an ion implanter wall. That is, there is a fear that metal as a chamber material of the ion implanter is introduced to the semiconductor layer 22. Thus, ions are desirably implanted with a silicon oxide film (SiO₂ film) such as a gate insulating film used as an ion-doping protective film. The ion-doping protective film is formed with a predetermined film thickness to obtain a desired impurity concentration distribution. The following description is given of an n-channel type TFT by way of example.

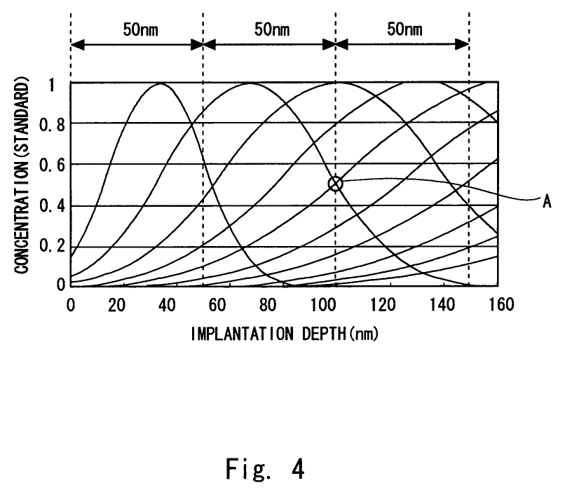

FIG. 4 shows impurity concentration distribution in the case of implanting boron ions to SiO₂. FIG. 4 shows simulation results of impurity concentration based on LSS RANGE STATISTICS (see “Projected Range Statistics, Semiconductor and Related Materials, 2nd edition, Halstead Press (1975), J. F. Gibbons, W. S. Johnson, S. W. Mylroie). In the simulation, the distribution is assumed to be Gaussian distribution with the implantation depth (Range) and standard deviation. As shown in FIG. 4, the peak concentration point is changed by changing an implantation energy of boron ions. In this embodiment, ions are implanted to the Si semiconductor layer 22 through the SiO₂ film. That is, a doping medium is a two-layer system of SiO₂ and Si. However, there is little difference in implantation depth and standard deviation between SiO₂ and Si at the implantation depth of 0 to 150 nm. Therefore, the result of FIG. 4 is used as an impurity concentration of this embodiment.

In a general TFT, the gate insulating film 23 has a film thickness of about 100 nm or less, and the semiconductor layer 22 has a film thickness of 50 nm or less. For example, ions are implanted through the 100 nm-thick gate insulating film 23 such that a peak concentration is obtained at the interface between the semiconductor layer 22 and the insulating substrate 21. In this case, as shown in FIG. 4, a concentration at the interface between the semiconductor layer 22 and the gate insulating film 23 is about ½ of the peak concentration (see “A” of FIG. 4). In this case, a boron concentration in the channel formation layer 224 increases, and the voltage Vth of the TFT is increased. To form the buried impurity layer 225 while suppressing a boron concentration in the channel formation layer 224, an impurity concentration profile should have a steep gradient. In this embodiment, as shown in FIG. 3B, the ion-doping protective film 231 is formed on the semiconductor layer 22 to prevent contamination upon the ion implantation. For example, the ion-doping protective film 231 is formed by depositing a SiO₂ film on the semiconductor layer 22 by PECVD. As shown in FIG. 4, as the implantation depth increases, the impurity concentration profile becomes gentle. Thus, the ion implantation through the ion-doping protective film 231 makes it difficult to obtain the steep gradient of the concentration profile. Thus, it is important to optimize the film thickness of the ion-doping protective film 231. Preferably, the ion-doping protective film 231 is an SiO₂ film having the thickness of 50 nm or less, for example, 10 to 20 nm. In the case of implanting ions through the SiO₂ film having the thickness of 50 nm or less to the semiconductor layer 22, a concentration at the interface between the semiconductor layer 22 and the gate insulating film 23 can be suppressed to 1/10 or less of the peak concentration. Moreover, to precisely control the voltage Vth of the TFT, it is desirable to additionally perform channel doping to the channel formation layer 224.

Ions are implanted to the semiconductor layer 22 through the ion-doping protective film 231 to form the buried impurity layer 225 of the second conductivity type such that a peak concentration appears around the interface with the insulating substrate 21 or on the insulating substrate 21 side. In an n-channel type TFT, a doped impurity is a p-type impurity such as boron (B). To compensate for the acceptor-like trap state density N_{A}, the buried impurity layer 225 has a concentration of 1×10¹⁶/cm³ or more at the interface with the insulating substrate 21.

After the formation of the buried impurity layer 225, as shown in FIG. 3C, the ion-doping protective film 231 is removed. Then, the surface of the insulating substrate 21 having the semiconductor layer 22 formed thereon is cleaned. As a result, the semiconductor layer 22 is exposed. After that, as shown in FIG. 3D, the gate insulating film 23 is formed on the exposed semiconductor layer 22. To reduce the interface state density at the interface with the semiconductor layer 22, the gate insulating film 23 is desirably formed by an SiO₂ film. In addition, conditions for forming the insulating film 23 desirably contain a large amount of hydrogen. To that end, the gate insulating film 23 is formed by PECVD or the like including TEOS (Tetra Ethyl Ortho Silicate).

A metal material as a gate electrode is deposited on the gate insulating film 23 by sputtering. Then, as shown in FIG. 3E, the gate electrode 24 is patterned into a desired shape through photo etching. As the gate electrode 24, for example, a high-melting-point material such as Mo or Ti can be used. Alternatively, a film stack mainly containing a low-resistance material such as Al and containing the high-melting-point material in an upper layer may be used as the gate electrode 24. Etching may be either dry or wet etching. That is, appropriate etching can be selected in accordance with a material for the gate electrode 24.

Finally, as shown in FIG. 3F, the first-conductivity-type impurity is introduced to the source region 221 and the drain region 222. For example, in an n-channel type TFT, doped impurity is an n-type impurity such as phosphorous (P). As a doping method, ion implantation or ion doping can be used. To reduce the parasitic capacitance resulting from an overlap between the gate electrode 24 and the source region 221, a self-aligned structure is desirable. Thus, impurities are implanted to the semiconductor layer 22 through the gate insulating film 23 with the gate electrode 24 used as a mask. At this time, the gate electrode 24 as a mask is formed over the channel region 223. Thus, the channel region 223 is not implanted with the first-conductivity-type impurity. Through the above steps, the TFT 20 of this embodiment is complete.

In this embodiment, to prevent metal contamination with metal of the ion implanter wall upon forming the buried impurity layer 225, the ion-doping protective film 231 is formed. However, ions may be implanted through the gate insulating film 23 in place of the ion-doping protective film 231. In this case, a step of forming the ion-doping protective film 231 (FIG. 3B) and a step of removing the film (FIG. 3C) can be skipped. Then, after the formation of the gate insulating film 23 (FIG. 3D), ions are implanted to the semiconductor layer 22 such that a peak concentration appears around the interface with the insulating substrate 21 or on the insulating substrate 21 side through the gate insulating film 23 to form the buried impurity layer 225. Further, to precisely control the voltage Vth of the TFT, it is desirable to additionally perform channel doping to the channel formation layer 224. Incidentally, the surface of the gate insulating film 23 is contaminated upon ion implantation. Thus, after the surface contaminant is removed by cleaning, the gate electrode 24 is desirably formed. In this case, the gate insulating film 23 has a film thickness of 50 nm or less. As a result, an impurity concentration at the interface between the semiconductor layer 22 and the gate insulating film 23 can be reduced.

As described above, in the structure of this embodiment, the buried impurity layer 225 of a second conductivity type with a peak concentration that appears around the interface with the insulating substrate 21 or on the insulating substrate 21 side is formed all over the lower portion of the channel region 223. The buried impurity layer 225 has an effect of compensating for the acceptor-like trap density N_{A} and suppressing an influence of the tapered portions 325 with a small thickness on the polysilicon film thickness tₛᵢ in Expression 1. That is, a hump hardly appears in the subthreshold characteristic, and the threshold voltage Vth of the TFT can be stabilized. Then, in this embodiment, ions are implanted through the ion-doping protective film 231 or gate insulating film 23 to form the buried impurity layer 225. Thus, the impurity concentration can be easily controlled and variations can be suppressed.

### Second Embodiment

A second embodiment of the present invention is described next with reference to the accompanying drawings. In this embodiment, the TFT 20 has an LDD structure. The LDD structure is such that the channel region 223 is not directly in contact with the source region 221 and the drain region 222 in a top-gate type TFT, and a first-conductivity-type region having an impurity concentration lower than the source region 221 and the drain region 222 is formed. Thus, the LDD structure is effective to reduce an electric field at the interface between the drain region 122 and the channel region 123, increase the breakdown voltage of the TFT, and improve a reliability thereof.

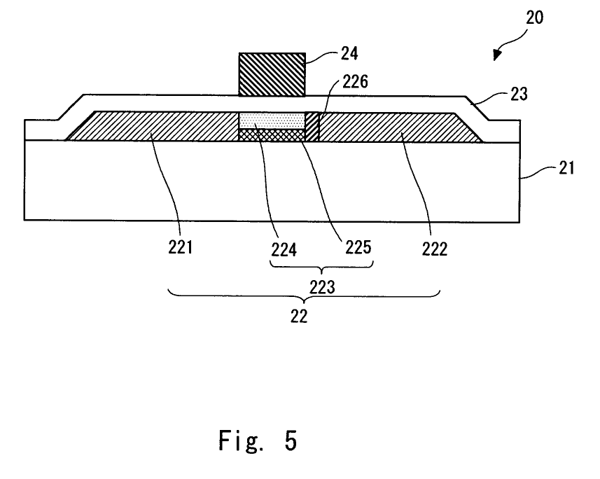

FIG. 5 is a sectional view of the TFT having the LDD structure according to the second embodiment. Description about the same components of the TFT as those of the first embodiment is omitted here. As shown in FIG. 5, according to the second embodiment, a low-concentration region 226 is formed in the drain region 222 in contact with the channel region 223 in addition to the structure as shown in the sectional view of FIG. 2B. The low-concentration region 226 is formed by implanting an n-type impurity such as phosphorous (P), for example, in an n-channel type TFT. Then, an n-type impurity concentration of the low-concentration region 226 is lower than the source region 221 and the drain region 222.

As described above, the TFT structured as shown in FIG. 5 has the following effects in addition to the effects of the first embodiment. The low-concentration region 226 formed in the drain region 222 outside the channel region 223 reduces a impurity concentration in the drain region 222, and an electric field near the drain. Then, the number of hot carriers at the interface between the channel region 223 and the drain region 222 is reduced. Thus, a source/drain breakdown voltage of the TFT increases, and a leak current in the subthreshold characteristics is decreased. At the same time, an electric field at the interface between the drain region 222 and the buried impurity layer 225 is reduced, and deterioration in junction breakdown voltage due to the buried impurity layer 225 is suppressed.

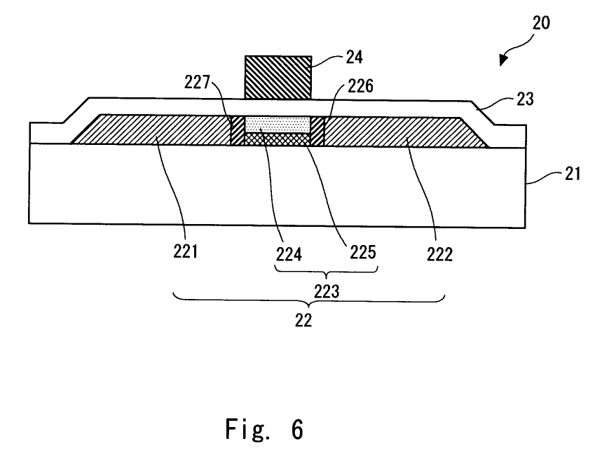

FIG. 6 is a sectional view of another example of the TFT having the LDD structure. In FIG. 6, a low-concentration region 227 is formed in the source region 221 in contact with the channel region 223 in addition to the low-concentration region 226 of FIG. 5. In the case of manufacturing the TFT of this structure, selective ion implantation is performed with the gate electrode 24 used as a mask to form the source/drain regions 221 and 222. After that, the gate electrode 24 is over-etched to remove the gate electrode 24 over the LDD region. The selective ion implantation is carried out again with the gate electrode 24 used as a mask. Thus, the LDD region can be formed. As compared with the structure of FIG. 5, the TFT of FIG. 6 includes low-concentration region 227 also on the source region 221 side. Thus, a parasitic resistance of the TFT increases, but a transfer step can be omitted from the manufacturing process, and thus the manufacturing process can be simplified.

As described above, in the TFT structured as shown in FIG. 6, low-concentration regions 226 and 227 are formed in both of the source region 221 and the drain region 222. Thus, the TFT structured as shown in FIG. 6 has the following effects in addition to the effects of the first embodiment. Similar to the structure of FIG. 5, a source/drain breakdown voltage of the TFT increases, and a leak current in the subthreshold characteristics is decreased. In addition, as discussed above, the manufacturing process can be simplified as compared with the structure of FIG. 5.

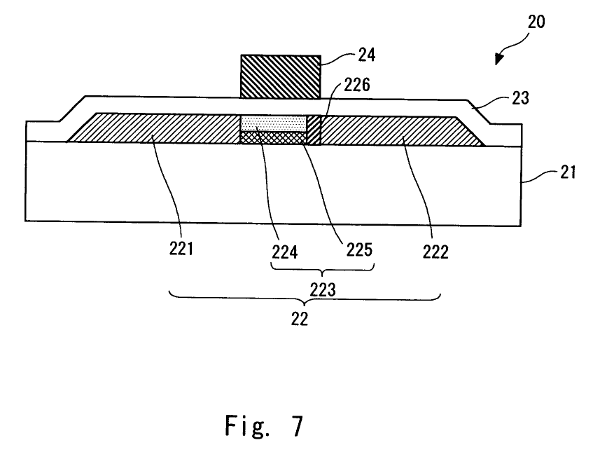

FIG. 7 is a sectional view of a TFT having a GOLD (Gate Overlapped LDD) structure according to the second embodiment. The TFT of FIG. 7 has a structure where the gate electrode 24 extends up to above the low-concentration region 226 in addition to the structure as shown in FIG. 5. Thus, a gate voltage of the gate electrode 24 is applied also to the low-concentration region 226. As a result, the number of carriers in the low-concentration region 226 increases. Thus, a resistance due to the LDD region is decreased, and a saturation current of the TFT increases.

As described above, the structure according to this embodiment as shown in FIG. 7 has the following effects in addition to the effects of the first embodiment. The TFT structured as shown in FIG. 7 has a GOLD structure, so a voltage is applied to the low-concentration region 226. Thus, the number of carriers in the low-concentration region 226 increases, and a parasitic resistance of the semiconductor layer 22 can be decreased. In addition, similar to the structure of FIG. 5, a source-drain voltage of the TFT increases, and a leak current in the subthreshold characteristics is decreased. Further, an electric field at the interface between the drain region 222 and the buried impurity layer 225 is reduced and deterioration in junction breakdown voltage due to the buried impurity layer 225 is suppressed.

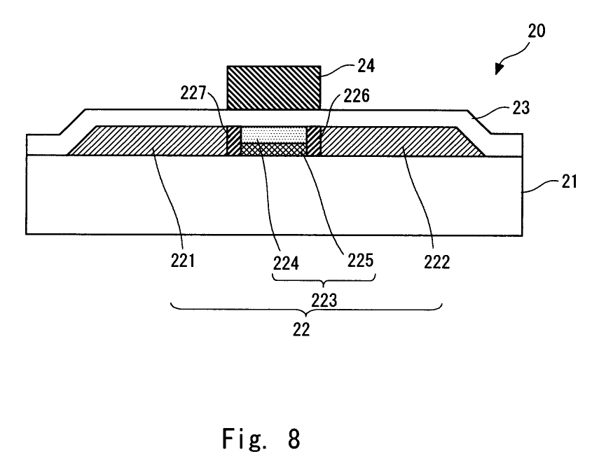

Further, FIG. 8 is a sectional view of another example of the TFT having the GOLD structure. In FIG. 8, the low-concentration region 227 is formed in the source region 221 in contact with the channel region 223 in addition to the structure as shown in the sectional view of FIG. 7. The gate electrode 24 extends over the low-concentration region 227. Thus, a gate voltage of the gate electrode 24 is applied onto the low-concentration region 226 and low-concentration region 227. Thus, the number of carriers in the low-concentration region 227 as well as the low-concentration region 226 increases.

As described above, the structure of this embodiment as shown in FIG. 8 has the following effects in addition to the effects of the first embodiment. In the GOLD structure, the low-concentration regions 226 and 227 are formed in both of the source region 221 and the drain region 222. Thus, in addition to the effects of the structure of FIG. 7, a parasitic resistance can be reduced in the low-concentration region 227 of the source region 221 as well as in the drain region 222. In addition, the manufacturing process can be simplified as compared with the structure of FIG. 7.

### Third Embodiment

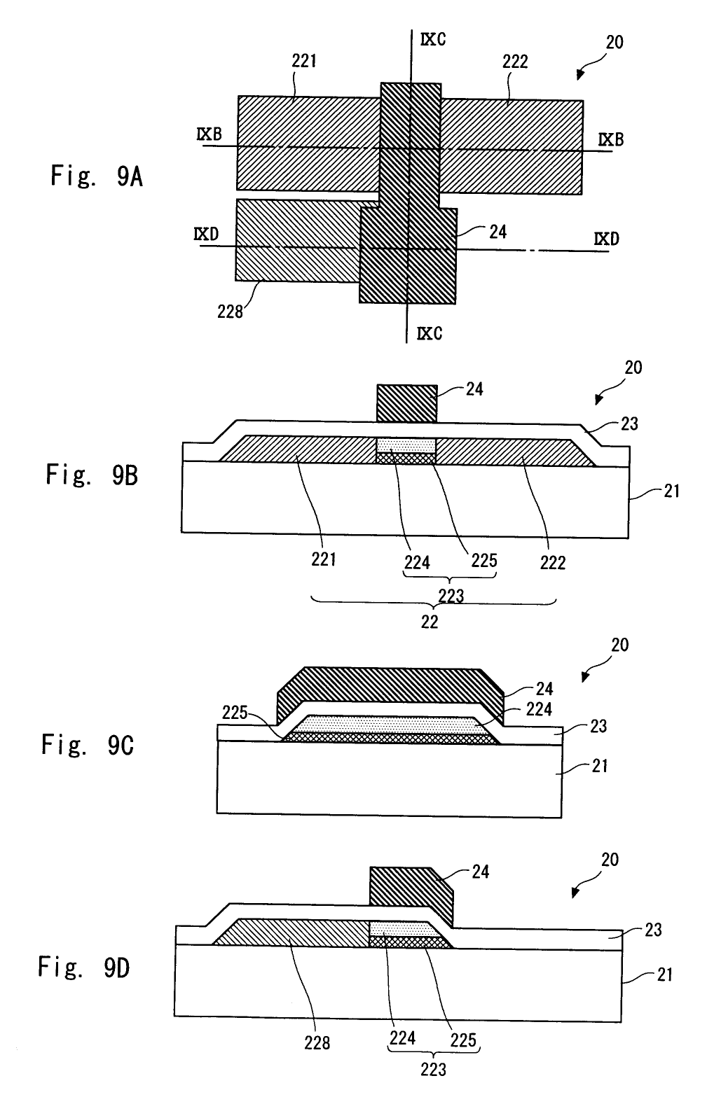

Referring to FIGS. 9A to 9D, a third embodiment of the present invention is described next. FIG. 9A is a plan view showing the structure of the TFT 20 according to the third embodiment. FIG. 9B is a sectional view taken along the line IXB-IXB of FIG. 9A. FIG. 9C is a sectional view taken along the line IXC-IXC of FIG. 9A. FIG. 9D is a sectional view taken along the line IXD-IXD of FIG. 9A.

In FIGS. 9A to 9D, the same components as those of FIG. 2 are denoted by identical reference numerals and description thereof is omitted here. The TFT of the third embodiment includes an extended pattern 228. The extended pattern 228 extends from the channel region 223 and protrudes from the gate electrode 24. In this embodiment, for example, the extended pattern 228 extends to the source region 221 side. In addition, the extended pattern 228 is doped with a second-conductivity-type impurity, and is formed in contact with the buried impurity layer 225 containing second-conductivity-type impurity as shown in FIG. 9D. That is, it is important to electrically connect the extended pattern 228 to the buried impurity layer 225. A potential of the extended pattern 228 is controlled through the line 26 formed over the extended pattern 228. As a result, minority carriers generated in the channel region 224 are extracted through the buried impurity layer 225 during operations of the TFT, and the TFT apparent early voltage can be increased. In addition, the backgate voltage of the TFT can be fixed. Therefore, as compared with the TFT of the related art, a backgate potential of which is floating, the stable voltage Vth can be controlled.

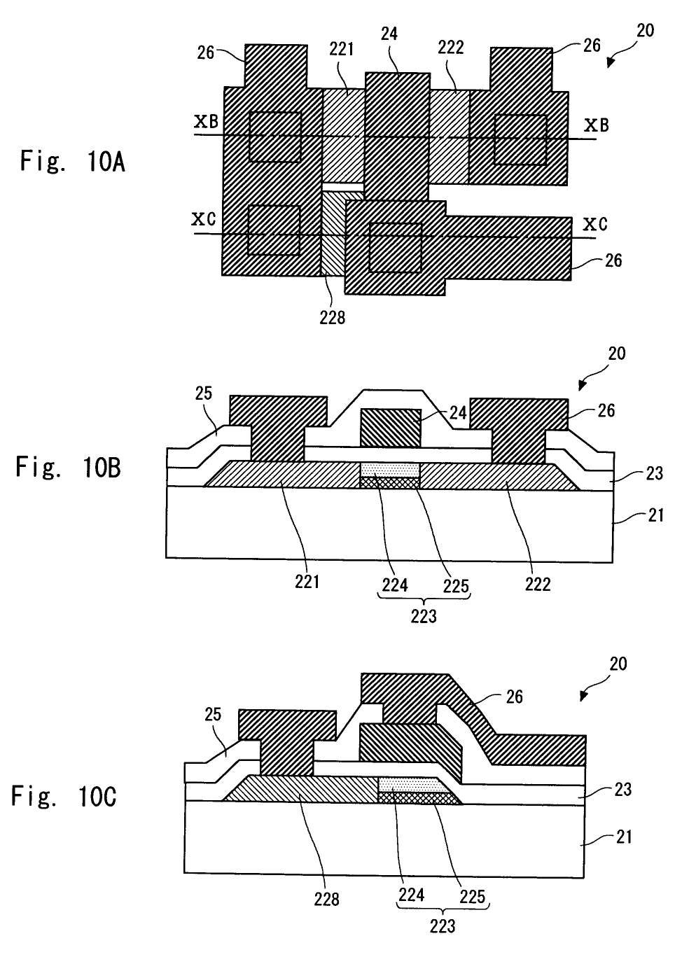

Further, benefits of the TFT according to this embodiment are described with reference to FIGS. 10A to 10C. FIGS. 10A to 10C show another example of the TFT of this embodiment. In FIGS. 10A to 10C, in addition to the structure of FIGS. 9A to 9D, the interlayer insulating film 25 and the line 26 are formed. For example, the line 26 connected to the source region 221 and the drain region 222 also functions as a signal line and a control line. The line 26 connected to the drain region 222 is partially connected to a pixel electrode (not shown) through a contact hole. The pixel electrode (not shown) is formed on the upper insulating film (not shown) covering the line 26. The interlayer insulating film 25 is formed on the gate insulating film 23 and the gate electrode 24. The line 26 configuring the circuit is electrically connected to the source region 221, the drain region 222, the gate electrode 24, and the extended pattern 228 through contact holes penetrating the interlayer insulating film 25 and gate insulating film 23. That is, the extended pattern 228 is electrically connected to the source region 221 through the line 26.

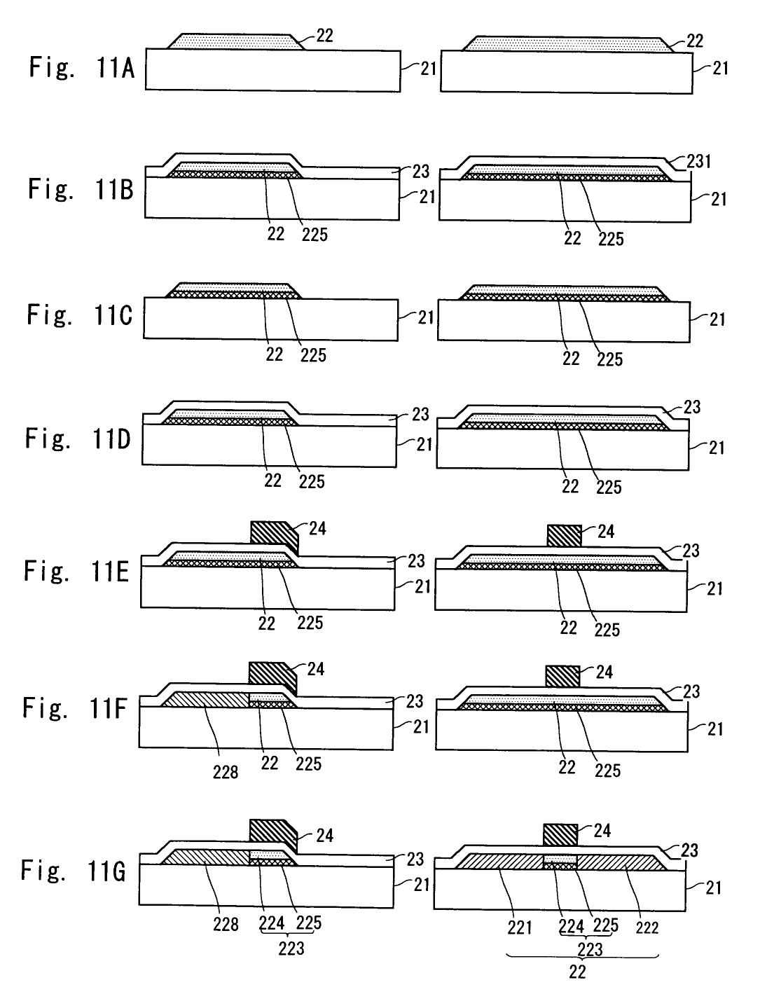

Referring next to FIGS. 11A to 11G, a manufacturing process of the TFT of the third embodiment is described. FIGS. 11A to 11G are sectional views of the TFT according to this embodiment in the manufacturing process. In FIGS. 11A to 11G, the structure of the TFT taken along the line IXD-IXD of FIG. 10A is shown on the left and the structure of the TFT taken along the line IXB-IXB of FIG. 10A on the right. Incidentally, description about the same steps as those of the first embodiment is omitted here.

First, the semiconductor layer 22 is also formed in a portion which the extended pattern 228 is to be formed as shown in the IXD-IXD sectional view of FIG. 11A. The semiconductor layer 22 is formed to partially protrude from the gate electrode 24 formed in a subsequent step. Referring next to FIG. 11B, the ion-doping protective film 231 is formed on the semiconductor layer 22. At this time, the ion-doping protective film 231 is formed also on the extended pattern 228. A second-conductivity-type impurity is doped to the semiconductor layer 22 including the extended pattern 228 through the ion-doping protective film 231 by ion implantation. As a result, the buried impurity layer 225 is formed. After the formation of the buried impurity layer 225, the ion-doping protective film 231 is removed as shown in FIG. 11C. As a result, the semiconductor layer 22 including the portion which the extended pattern 228 is to be formed is exposed. Then, the surface of the insulating substrate 21 having the semiconductor layer 22 formed thereon is cleaned and then the gate insulating film 23 is formed as shown in FIG. 11D. The semiconductor layer 22 including the portion which the extended pattern 228 is to be formed is covered with the gate insulating film 23. Next, a metal material for forming the gate electrode is deposited on the gate insulating film 23 by sputtering, and the gate electrode 24 is patterned into a desired shape through photo etching as shown in FIG. 11E. The gate electrode 24 is patterned not to remain over the portion which the extended pattern 228 is to be formed.

After the formation of the gate electrode 24, the second-conductivity-type impurity is introduced through the gate insulating film 23 by ion implantation to thereby form the extended pattern 228 as shown in FIG. 11F. For example, the gate electrode 24 is partially used as a mask, and the source region 121, the drain region 122, or other such regions not to be doped with the second-conductivity-type impurity are covered with a resist or the like. Under this state, the impurity maybe implanted. Finally, as shown in FIG. 11G, the source region 221 and the drain region 222 are doped with the first-conductivity-type impurity. For example, the impurity may be introduced while a resist is applied to a region not to be doped with the first-conductivity-type impurity such as the extended pattern 228.

Further, the interlayer insulating film 25 and the line 26 are formed. These films can be formed by general photolithography process. That is, thin film formation, resist coating, exposure, development, etching, and removal of resist are repeated. In addition, a material for the thin film can be appropriately selected from known materials in accordance with characteristics of each layer. For example, after the formation of the interlayer insulating film 25, contact holes are formed. The contact holes are formed to expose the source region 221, the drain region 222, and the extended pattern 228. Then, a conductive film made of Al or an Al alloy is formed on the interlayer insulating film 25. The conductive film is patterned by photolithography process to thereby form the line 26 as shown in FIGS. 10A to 10C.

As described above, in this embodiment, the extended pattern 228 formed in contact with the buried impurity layer 225 is formed to protrude from the gate electrode 24 outside of the channel region 223. A potential is controlled through the line 26 to thereby set the potential of the extended pattern 228 equal to that of the source region 221. Then, minority carriers generated in the channel region 223 during operations of the TFT can be easily extracted to the source region 221 through the buried impurity layer 225. Thus, minority carriers are not accumulated, and the TFT apparent early voltage is increased. That is, a value of λ is reduced, and in addition to the effects of the first embodiment, stable voltage-current characteristics are realized. In addition, since the TFT backgate voltage is fixed, as compared with the TFT of the related art, a backgate potential of which is floating, the stable voltage Vth can be controlled.

This embodiment describes the TFT of the self-aligned structure by way of example, but the TFT having the LDD structure may be used. That is, the second and third embodiments may be used in combination. In either case, similar effects to the self-aligned structure can be obtained. In FIGS. 10A to 10C, the extended pattern 228 is connected to the source region 221 through the line 26 by way of example, but a different potential level may be set to control the voltage Vth of the TFT. In addition, the extended pattern 228 can be directly connected to another potential not through the line 26.

Incidentally, a general low-temperature polysilicon TFT that is turned into polysilicon by laser annealing is described in the present invention by way of example, but polysilicon TFTs manufactured by the other processes can be used. In place of the polysilicon, crystalline silicon TFT such as a microcrystal silicon TFT can be employed. In addition, in the description of the present invention, the semiconductor layer 22 has a film thickness of 50 nm or less, but the semiconductor layer 22 can be made thicker by utilizing a low-leak-current characteristic of the present invention. For example, the semiconductor layer 22 may have the thickness of 70 nm or more. As a result, an impurity concentration at the interface between the semiconductor layer 22 and the gate insulating film 23 can be further reduced.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A thin film transistor array substrate, comprising:
a crystalline silicon layer including a source region having a first conductivity type, a drain region having the first conductivity type, and a channel region between the source region and the drain region, and formed over a substrate; and
a gate electrode opposite to the channel region with a gate insulating film interposed therebetween,
wherein the channel region contains an impurity of a second conductivity type doped with a predetermined distribution in a film thickness direction, and
the impurity of the second conductivity type has a peak concentration point around an interface between the channel region and the substrate or on the substrate side.

2. The thin film transistor array substrate, according to claim 1, wherein the second-conductivity-type impurity has a concentration of about 1×10¹⁶/cm³ or more at an interface between the channel region and the substrate.

3. The thin film transistor array substrate, according to claim 1, further comprising:
a low-concentration region having a first-conductivity-type impurity concentration lower than the drain region and formed between the channel region and the drain region.

4. The thin film transistor array substrate, according to claim 3, further comprising:
a low-concentration region having a first-conductivity-type impurity concentration lower than the drain region and formed between the channel region and the drain region.

5. The thin film transistor array substrate, according to claim 1, further comprising:
an extended pattern extending from the channel region and protruding from the gate electrode and including the second-conductivity-type impurity.

6. The thin film transistor array substrate, according to claim 5, further comprising:
a conductive pattern connected to the extended pattern.

7. The thin film transistor array substrate, according to claim 5, wherein the extended pattern is electrically connected to the source region.

8. A display device comprising the thin film transistor array substrate according to claim 1.

9. A method of manufacturing a thin film transistor array substrate including: a crystalline silicon layer including a source region having a first conductivity type, a drain region having the first conductivity type, and a channel region between the source region and the drain region, and formed over a substrate; and a gate electrode opposite to the channel region with a gate insulating film interposed therebetween, comprising:
forming the crystalline silicon layer; and
introducing the second-conductivity-type impurity in the channel region with a predetermined distribution in a film thickness direction such that a peak concentration point of the second-conductivity-type impurity in the channel region appears around an interface between the channel region and the substrate or on the substrate side.

10. The method of manufacturing a thin film transistor array substrate according to claim 9, further comprising:
forming a protective film on the crystalline silicon layer,
wherein the protective film is removed to expose the crystalline silicon layer after the second-conductivity-type impurity is introduced to the crystalline silicon layer through the protective film, and
the gate insulating film is formed on the exposed crystalline silicon layer.

11. The method of manufacturing a thin film transistor array substrate according to claim 9, wherein the second-conductivity-type impurity has a concentration of about 1×10¹⁶/cm³ or more at an interface between the channel region and the substrate.

12. The method of manufacturing a thin film transistor array substrate according to claim 9, wherein
an extended pattern that extends from the channel region is formed upon forming the crystalline silicon layer;
the second-conductivity-type impurity is introduced to the channel region and the extended pattern upon introducing the second-conductivity-type impurity; and
the second-conductivity-type impurity is introduced to the extended pattern that protrudes from the gate electrode after the gate electrode is formed over the crystalline silicon layer.

13. The method of manufacturing a thin film transistor array substrate according to claim 12, further comprising:
forming a conductive pattern connected to the extended pattern.
